(19) United States
(12) Patent Application Publication
(10) Pub. No.: US 2014/0317471 A1
(43) Pub. Date: Oct. 23, 2014

(54) SEMICONDUCTOR MEMORY DEVICES INCLUDING SEPARATELY DISPOSED ERROR-CORRECTING CODE (ECC) CIRCUITS

(71) Applicant: Samsung Electronics Co., Ltd., Suwon-Si (KR)

(72) Inventors: Jang-woo RYU, Seoul (KR); Chul-sung PARK, Seoul (KR); Tae-young OH, Seoul (KR); Chan-yong LEE, Suwon-si (KR); Tae-Seong JANG, Yongin-si (KR); Hoi-ju CHUNG, Yongin-si (KR); Gong-heum HAN, Hwaseong-si (KR)

(73) Assignee: Samsung Electronics Co., Ltd., Suwon-Si (KR)

(21) Appl. No.: 14/225,725

(22) Filed: Mar. 26, 2014

Related U.S. Application Data
(60) Provisional application No. 61/813,246, filed on Apr. 18, 2013.

(30) Foreign Application Priority Data
Jul. 12, 2013 (KR) 10-2013-0082461

(51) Int. Cl. G06F 11/10; H03M 13/13

(52) U.S. Cl. CPC G06F 11/10; H03M 13/13
USPC 714/764

(57) ABSTRACT

A semiconductor memory device may comprise: at least one bank, each of the at least one bank including a plurality of memory cells; an error-correcting code (ECC) calculator configured to generate syndrome data for detecting an error bit from among parallel data bits read out from the plurality of memory cells of each of the at least one bank; an ECC corrector separated from the ECC calculator, the ECC corrector configured to correct the error bit from among the parallel data bits by using the syndrome data and configured to output error-corrected parallel data bits; and/or a data serializer configured to receive the error-corrected parallel data bits and configured to convert the error-corrected parallel data bits into serial data bits.

### CROSS-REFERENCE TO RELATED APPLICATION(S)

This application claims the benefit of U.S. Provisional Patent Application No. 61/813,246, filed on Apr. 18, 2013, in the U.S. Patent and Trademark Office (USPTO), the entire contents of which are incorporated herein by reference. This application also claims priority from Korean Patent Application No. 10-2013-0082461, filed on Jul. 12, 2013, in the Korean Intellectual Property Office (KIPO), the entire contents of which are incorporated herein by reference.

### BACKGROUND

1. Field

Some example embodiments relate to semiconductor memory devices. Some example embodiments relate to memory devices whose performance is improved by separately disposing error-correcting code (ECC) circuits therein.

2. Description of Related Art

A storage capacity of a semiconductor memory device has increased as a manufacturing process technology has been developed. As a scaling-down process technology has been developed, the number of weak memory cells has been increased, thereby reducing the production yield of semiconductor memory devices and failing to ensure a sufficient storage capacity. In order to solve these problems, a semiconductor memory device employs an ECC circuit. However, as the ECC circuit operates, the semiconductor memory device may suffer a timing overhead and/or a chip-size overhead.

### SUMMARY

The inventive concepts provide semiconductor memory devices that separately dispose error-correcting code (ECC) circuits.

In some example embodiments, a semiconductor memory device may comprise: at least one bank, each of the at least one bank including a plurality of memory cells; an error-correcting code (ECC) calculator configured to generate syndrome data for detecting an error bit from among parallel data bits read out from the plurality of memory cells of each of the at least one bank; an ECC corrector separated from the ECC calculator, the ECC corrector configured to correct the error bit from among the parallel data bits by using the syndrome data and configured to output error-corrected parallel data bits; and/or a data serializer configured to receive the error-corrected parallel data bits and configured to convert the error-corrected parallel data bits into serial data bits.

In some example embodiments, the semiconductor memory device may further comprise data line sense amplifiers configured to sense and amplify the parallel data bits read out from the plurality of memory cells. The ECC calculator may be adjacent to the data line sense amplifiers. The ECC corrector may be adjacent to the data serializer.

In some example embodiments, each of the at least one bank may comprise a plurality of first memory cell blocks that comprise first memory cells; and/or a second memory block that comprises second memory cells, and is configured to store in the second memory cells parity bits of an ECC operation for remedying a weak cell from among the first memory cells in the first memory cell blocks.

In some example embodiments, the ECC calculator may be configured to receive and calculate the parallel data bits read out from the first memory cell blocks and the parity bits read out from the second memory cell block.

In some example embodiments, the semiconductor memory device may further comprise an input/output (I/O) circuit unit configured to output to a data I/O pad the serial data bits corresponding to a burst length that are output from the data serializer.

In some example embodiments, the data serializer may be configured to divide the error-corrected parallel data bits into bit groups of the burst length in response to a clock signal, and/or the data serializer may be configured to output the bit groups as the serial data bits.

In some example embodiments, the data serializer may be configured to divide the error-corrected parallel data bits into a high-order bit group and a low-order bit group of the burst length, and/or the data serializer may be configured to output the high-order bit group and the low-order bit group as the serial data bits.

In some example embodiments, a semiconductor memory device may comprise: a plurality of banks, each of the plurality of banks including a plurality of memory cells; an error-correcting code (ECC) calculator connected to each of the plurality of banks, the ECC calculator configured to generate syndrome data for detecting an error bit from among parallel data bits read out from the plurality of memory cells; a data serializer configured to receive the parallel data bits and configured to convert the parallel data bits into serial data bits; and/or an ECC corrector configured to correct an error bit from among the serial data bits by using the syndrome data and configured to output error-corrected serial data bits.

In some example embodiments, the semiconductor memory device may further comprise data line sense amplifiers configured to sense and amplify the parallel data bits read out from the plurality of memory cells. The ECC calculator may be adjacent to the data line sense amplifiers.

In some example embodiments, the ECC corrector may be shared by the plurality of banks, and/or the ECC corrector may be configured to output the error-corrected serial data bits of each of the plurality of banks

In some example embodiments, each of the plurality of banks may comprises a plurality of first memory cell blocks that comprise first memory cells; and/or a second memory cell block that comprises second memory cells, and is configured to store in the second memory cells parity bits of an ECC operation for remedying a weak cell from among the first memory cells in the first memory cell blocks. The ECC calculator may be configured to receive and calculate the parallel data bits read out from the first memory cells and the parity bits read out from the second memory cells.

In some example embodiments, the semiconductor memory device may further comprise an input/output (I/O) circuit unit configured to output to a data I/O pad the error-corrected serial data bits corresponding to a burst length.

In some example embodiments, the ECC corrector may be adjacent to the I/O circuit unit.

In some example embodiments, the data serializer may be configured to divide the parallel data bits into bit groups of the burst length in response to a clock signal, and/or the data serializer may be configured to output the bit groups as the serial data bits.

In some example embodiments, the data serializer may be configured to divide the parallel data bits into a high-order bit group and a low-order bit group of the burst length, and/or the data serializer may be configured to output the high-order bit group and the low-order bit group as the serial data bits.

In some example embodiments, a semiconductor memory device may comprise at least one bank, each of the at least one bank including a plurality of memory cells; at least one data sensing unit that comprises an error-correcting code (ECC) calculator and a data serializer, the ECC calculator configured to generate syndrome data for detecting an error bit from among parallel data bits read out from the plurality of memory cells; an ECC corrector configured to correct the error bit by using the syndrome data and configured to output error-corrected data bits; and/or an input/output (I/O) circuit unit configured to output the error-corrected data bits.

In some example embodiments, the at least one data sensing unit may include the ECC corrector.

In some example embodiments, the data serializer may be operatively connected between the ECC corrector and the I/O circuit unit.

In some example embodiments, the at least one data sensing unit may not include the ECC corrector.

In some example embodiments, the ECC corrector may be operatively connected between the ECC calculator and the I/O circuit unit, and/or the ECC corrector may be operatively connected between the data serializer and the I/O circuit unit.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIG. 1 is a block diagram illustrating a semiconductor memory device including an error-correcting code (ECC) circuit that is separately disposed, according to some example embodiments of the inventive concepts;

FIG. 2 is a block diagram illustrating a bank and a data sensing unit of the semiconductor memory device of FIG. 1, according to some example embodiments of the inventive concepts;

FIG. 3 is a block diagram illustrating an ECC calculator and an ECC corrector, according to some example embodiments of the inventive concepts;

FIG. 4 is a block diagram illustrating a data serializer according to some example embodiments of the inventive concepts;

FIG. 5 is a timing diagram for explaining an operation of a first multiplexer, according to some example embodiments of the inventive concepts;

FIG. 6 is a timing diagram for explaining an operation of the data serializer of FIG. 4, according to some example embodiments of the inventive concepts;

FIG. 7 is a block diagram illustrating a semiconductor memory device according to some example embodiments of the inventive concepts;

FIG. 8 is a block diagram illustrating a bank and a data sensing unit of the semiconductor memory device of FIG. 7, according to some example embodiments of the inventive concepts;

FIGS. 9 through 11 are perspective views illustrating memory modules each including a dynamic random access memory (DRAM) including an ECC circuit that is separately disposed, according to some example embodiments of the inventive concepts;

FIG. 12 is a perspective view illustrating a semiconductor device having a stacked structure including DRAM semiconductor layers each including an ECC circuit that is separately disposed, according to some example embodiments of the inventive concepts;

FIG. 13 is a block diagram illustrating a memory system including a DRAM including an ECC circuit that is separately disposed, according to some example embodiments of the inventive concepts;

FIG. 14 is a block diagram illustrating a data processing system including a DRAM including an ECC circuit that is separately disposed, according to some example embodiments of the inventive concepts;

FIG. 15 is a view illustrating a server system including a DRAM including an ECC circuit that is separately disposed, according to some example embodiments of the inventive concepts; and

FIG. 16 is a block diagram illustrating a computer system on which a DRAM including an ECC circuit that is separately disposed is mounted, according to some example embodiments of the inventive concepts.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, their shapes are not intended to illustrate the actual shape of a region of a device, and their shapes are not intended to limit the scope of the example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

A storage capacity of a semiconductor memory device, for example, a dynamic random access memory (DRAM), has increased as a manufacturing process technology has been developed. As a scaling-down process technology has been developed, the number of weak memory cells has increased. Also, as a DRAM having finite data retention has continued to be scaled down, a capacitance value of a cell capacitor has decreased and a bit error rate (BER) has increased, thereby reducing reliability of data stored in a memory cell. In some example embodiments of the inventive concepts, data integrity of a semiconductor memory device may be ensured by employing an error-correcting code (ECC) circuit in the semiconductor memory device to correct error bits.

Reference will now be made to example embodiments, which are illustrated in the accompanying drawings, wherein like reference numerals may refer to like components throughout.

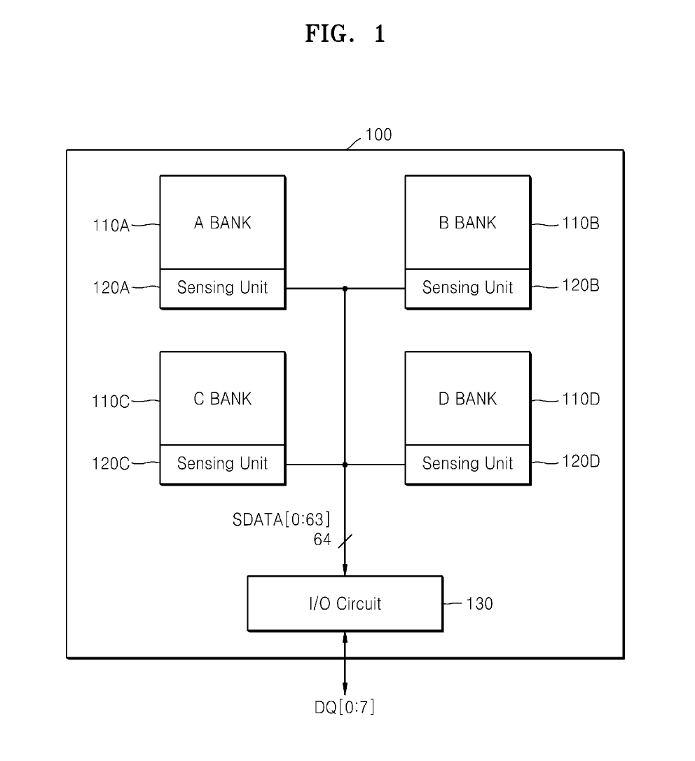

FIG. 1 is a block diagram illustrating a semiconductor memory device 100 including an ECC circuit that is separately disposed, according to some example embodiments of the inventive concepts.

Referring to FIG. 1, the semiconductor memory device 100 includes a plurality of banks, that is, A through D banks 110A through 110D, data sensing units 120A through 120D respectively connected to the A through D banks 110A through 110D, and an input/output (I/O) circuit unit 130. Each of the A through D banks 110A through 110D include a plurality of memory cells. Although the semiconductor memory device 100 includes 4 banks in FIG. 1, example embodiments are not limited thereto and the semiconductor memory device 100 may include banks more or less than 4 banks.

The data sensing units 120A through 120D respectively sense and amplify parallel data bits read out from the A through D banks 110A through 110D, and perform error detection and error correction on the sensed and amplified parallel data bits. Also, the data sensing units 120A through 120D convert the error-corrected parallel data bits of the A through D banks 110A through 110D into serial data bits SDATA[0:63] and outputs the serial data bits SDATA[0:63].

The I/O circuit unit 130 receives the serial data bits SDATA[0:63] output from the data sensing units 120A through 120D, sequentially arrange the serial data bits SDATA[0:63] as data bits corresponding to a burst length BL, and outputs the sequentially arranged data bits to data I/O pads DQ[0:7].

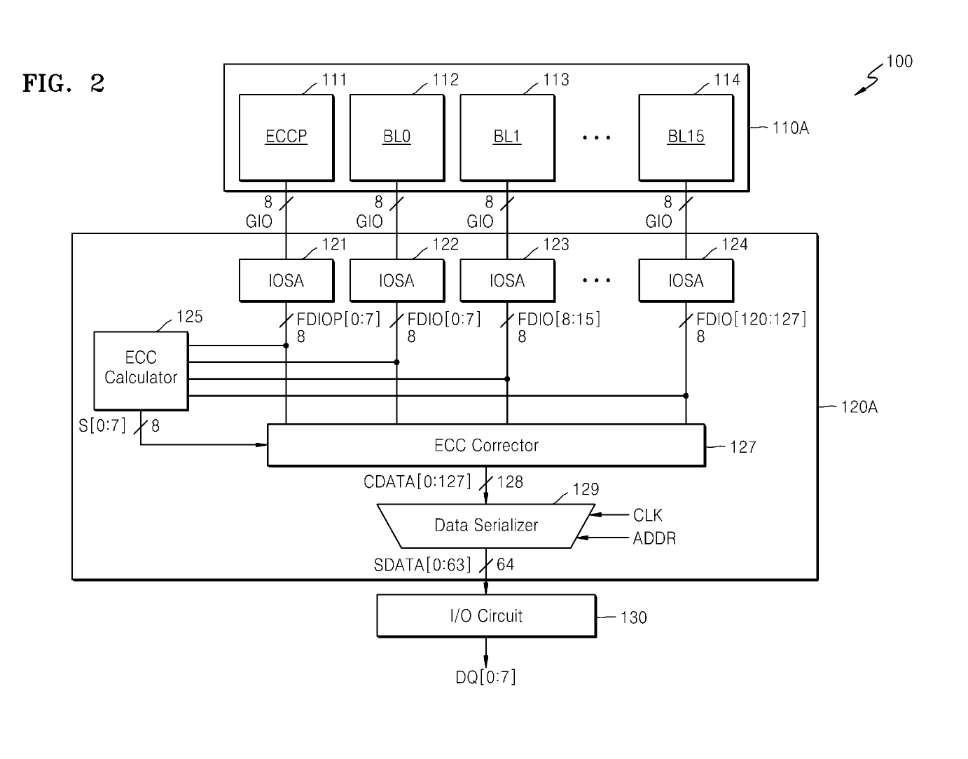

FIG. 2 is a block diagram illustrating a bank and a data sensing unit of the semiconductor memory device 100 of FIG. 1, according to some example embodiments of the inventive concepts. In FIG. 2, the A bank 110A and the data sensing unit 120A connected to the A bank 110A of FIG. 1 will be exemplarily explained. Descriptions of the A bank 110A and the data sensing unit 120A may apply to the remaining B through D banks 110B through 110D and the data sensing units 120B through 120D.

Referring to FIG. 2, the A bank 110A includes a plurality of cell blocks 111 through 114 in which a plurality of memory cells are arranged in rows and columns. The cell blocks 111 through 114 may be defined variously. For example, the cell blocks 111 through 114 may be defined as areas in which data stored in the memory cells of the cell blocks 111 through 114 is input/output to correspond to a corresponding data I/O pad DQ, or may be defined as areas in which data is input/output to correspond to the burst length BL for read and write operations of the semiconductor memory device 100.

In FIG. 2, the cell blocks 111 through 114 are defined as areas in which data is input/output to correspond to the burst length BL. The burst length BL refers to the maximum number of memory cells that may be accessed in response to a corresponding read or write command. The burst length BL may be set to any of BL4, BL8, BL16, and BL32. For example, when the burst length BL is set to BL16, for convenience of explanation, the cell block to/from which data corresponding to a first BL is written/read, from among the cell blocks 111 through 114, is referred to as a BL0 cell block 112, a cell block to/from which data corresponding to a second BL is written/read is referred to as a BL1 cell block 113, and a cell block to/from which data corresponding to a last BL is written/read is referred to as a BL15 cell block 114.

Also, the cell blocks 111 through 114 may include a cell block in which parity bits used in a process of detecting/correcting an error during an ECC operation are stored. For convenience of explanation, the cell block in which the parity bits are stored is referred to as an ECCP cell block 111.

The cell blocks 111 through 114 may include the ECCP cell block 111, and the BL0 through BL15 cell blocks 112 through 114. The ECCP cell block 111 and the BL0 through BL15 cell blocks 112 through 114 are connected to the data sensing unit 120A through first data lines GIO. Each of the first data lines GIO includes one pair of data lines that have a complementary relationship therebetween. When the semiconductor memory device 100 includes 8 data I/O pads, for example, 8 DQ pads DQ[0:7], each of the ECCP cell block 111 and the BL0 through BL15 cell blocks 112 through 114 may be connected to 8 first data lines GIO.

The total number of the first data lines GIO connected to the BL0 through BL15 cell blocks 112 through 114 is 128, and the 128 first data lines GIO are connected to the 8 DQ pads DQ[0:7]. That is, 128-bit data on the first data lines GIO connected to the BL0 through BL15 cell blocks 112 through 114 is input/output to/from the semiconductor memory device 100 through the 8 DQ pads DQ[0:7]. In this case, each of the DQ pads DQ[0:7] inputs/outputs 16-bit data corresponding to the burst length BL16.

The number of the first data lines GIO connected to the ECCP cell block 111 is 8. In order to detect and correct an error bit in the 128-bit data of the BL0 through BL15 cell blocks 112 through 114, a Hamming type ECC algorithm using 8-bit parity bits may be used.

The number of bits of unit data to be error-corrected and the number of parity bits may vary according an ECC algorithm used to detect and correct an error. For example, 6-bit parity bits may be used for 32-bit data, and 7-bit parity bits may be used for 64-bit data. Accordingly, the number of the first data lines GIO connected to the BL0 through BL15 cell blocks 112 through 114 and the number of the first data lines GIO connected to the ECCP cell block 111 may vary according to the ECC algorithm.

The first data lines GIO connected to the ECCP cell block 111 and the BL0 through BL15 cell blocks 112 through 114 are connected to the data sensing unit 120A. The data sensing unit 120A senses and amplifies parallel data bits read out from the ECCP cell block 111 and the BL0 through BL15 cell blocks 112 through 114 transmitted through the first data lines GIO. The data sensing unit 120A performs error detection and error correction on the sensed and amplified parallel data bits. The data sensing unit 120A converts error-corrected parallel data bits CDATA[0:127] into serial data bits SDATA[0:63] and outputs the serial data bits SDATA[0:63]. The data sensing unit 120A includes data line sense amplifiers (IOSA) 121 through 124, an ECC calculator 125, an ECC corrector 127, and a data serializer 129.

The data line sense amplifiers 121 through 124 respectively sense and amplify data bits read out from the ECCP cell block 111 and the BL0 through BL15 cell blocks 112 through 114 transmitted through the first data lines GIO. 8-bit parity bits read out from the ECCP cell block 111 are sensed and amplified by the data line sense amplifier 121 and are transmitted to a second data line FDIOP. 128-bit parallel data bits read out from the BL0 through BL15 cell blocks 112 through 114 are transmitted to a second data line FDIO through the data line sense amplifiers 122 through 124. The sensed and amplified data bits transmitted to the second data lines FDIOP and FDIO are provided to the ECC calculator 125 and the ECC corrector 127.

The ECC calculator 125 and the ECC corrector 127 perform various functions related to error detection and error correction performed on the data bits transmitted to the second data lines FDIOP and FDIO. The ECC calculator 125 generates syndrome data S[0:7] by calculating the 128-bit parallel data bits transmitted through second data lines FDIO[0:127] from the BL0 through BL15 cell blocks 112 through 114 and the 8-bit parity bits transmitted to the second data line FDIOP[0:7] from the ECCP cell block 111. The ECC corrector 127 may output error-corrected data bits CDATA[0:127] by detecting an error bit from among the 128-bit parallel data bits on the second data lines FDIO[0:127] and correcting the error bit by using the syndrome data S[0:7].

The ECC calculator 125 and the ECC corrector 127 are essential elements that constitute the ECC circuit. The ECC circuit performs an ECC encoding operation that generates parity bits for write data received from the outside during a write operation of the semiconductor memory device 100. The parity bits of the ECC encoding operation are stored in memory cells of the ECCP cell block 111. The ECC circuit performs an ECC decoding operation that detects a position of an error bit from among the 128-bit parallel data and corrects the error bit by using the 128-bit parallel data bits read out from the BL0 through BL15 cell blocks 112 through 114 and the 8-bit parity bits read out from the ECCP cell block 111. The ECC decoding operation of some example embodiments will be explained in detail.

Although the ECC calculator 125 and the ECC corrector 127 are closely connected to each other during the ECC decoding operation, the ECC calculator 125 and the ECC corrector 127 are separated from each other. The ECC calculator 125 is disposed adjacent to the data line sense amplifiers 121 through 124, and the ECC corrector 127 is disposed adjacent to the data serializer 129.

The error-corrected parallel data bits CDATA[0:127] output from the ECC corrector 127 are provided to the data serializer 129. The data serializer 129 receives the error-corrected 128-bit parallel data bits CDATA[0:127] in response to a clock signal CLK and an address signal ADDR, converts the error-corrected parallel data bits CDATA[0:127] into, for example, 64-bit serial data bits SDATA[0:63], and outputs the 64-bit serial data bits SDATA[0:63]. The data serializer 129 is used to reduce a chip-size overhead due to bussing of the 128-bit data lines.

The 64-bit serial data bits SDATA[0:63] output from the data serializer 129 are provided to the I/O circuit unit 130. The I/O circuit unit 130 receives the serial data bits SDATA[0:63], sequentially arranges the serial data bits SDATA[0:63] as data bits corresponding to the burst length BL, and outputs the sequentially arranged serial data bits SDATA[0:63] to the data I/O pads DQ[0:7].

Although the data serializer 129 converts the 128-bit parallel data bits CDATA[0:127] into the 64-bit serial data bits SDATA[0:63] in FIG. 2, the present embodiment is not limited thereto and the data serializer 129 may convert the 128-bit parallel data bits CDATA[0:127] into 32-bit or 16-bit serial data. In this case, a chip-size overhead may be further reduced due to reduced bussing of data lines.

The semiconductor memory device 100 is designed such that the ECC circuit including the ECC calculator 125 and the ECC corrector 127 is disposed between the data line sense amplifiers 121 through 124 and the data serializer 129, thereby reducing a timing overhead as well as a chip-size overhead.

A semiconductor memory device having a timing overhead which is designed differently from the semiconductor memory device 100 will be explained. For example, the semiconductor memory device may be designed such that the data line sense amplifiers 121 through 124 and the data serializer 129 are disposed adjacent to each other, and the ECC calculator 125 and the ECC corrector 127 receive an output of the data serializer 129.

In this case, the semiconductor memory device is designed to convert 128-bit parallel data on the second data lines FDIO[0:127] which is read out from the BL0 through BL15 cell blocks 112 through 114 into 64-bit serial data, and enables the ECC calculator 125 and the ECC corrector 127 to receive the 64-bit serial data and 8-bit parity bits on the second data lines FDIOP[0:7] which are read out from the ECCP cell block 111.

In this case, the ECC calculator 125 and the ECC corrector 127 need to convert again the 64-bit serial data into 128-bit parallel data, in order to detect and correct an error bit in the 64-bit serial data by using the 8-bit parity bits. The reason why the serial to parallel conversion operation needs to be performed is that an XOR operation is to be performed on the 8-bit parity bits and the 128-bit parallel data in order to calculate syndrome data in an ECC algorithm for detecting an error bit. Accordingly, a data access time tAA of the semiconductor memory device is increased due to the addition of a time taken to perform the serial to parallel conversion operation, thereby generating a timing overhead.

In the semiconductor memory device 100 of the present embodiment, however, since the 128-bit parallel data bits on the second data lines FDIO[0:127] which are read out from the BL0 through BL15 cell blocks 112 through 114 are error-corrected by the ECC calculator 125 and the ECC corrector 127, and then are provided to the data serializer 129, the additional data access time tAA is not necessary. Accordingly, the semiconductor memory device 100 has no timing overhead even when employing the ECC calculator 125 and the ECC corrector 127.

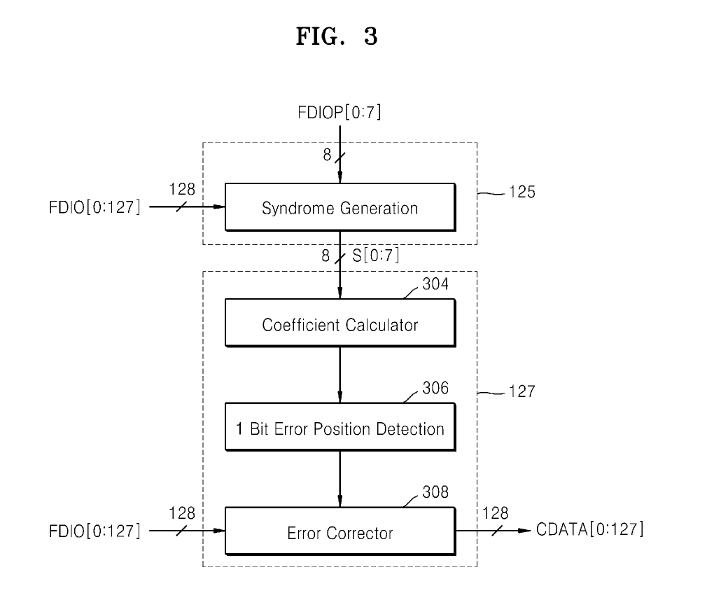

FIG. 3 is a block diagram illustrating the ECC calculator 125 and the ECC corrector 127, according to some example embodiments of the inventive concepts.

Referring to FIG. 3, the ECC calculator 125 may receive 128-bit parallel data bits transmitted through the second data lines FDIO[0:127] and 8-bit parity bits transmitted through the second data line FDIOP[0:7], and may generate syndrome data S[0:7] by using an XOR array operation.

The ECC corrector 127 includes a coefficient calculator 304, an error bit position detector 306, and an error corrector 308. The coefficient calculator 304 may calculate a coefficient of an error position equation by using the syndrome data S[0:7]. At the same time, the error bit position detector 306 may calculate a position of an error bit from among the 128-bit data bits of the second data lines FDIO[0:127] by using the syndrome data S[0:7]. The error bit position detector 306 may calculate, for example, a position of a 1-bit error from among the 128-bit data bits of the second data lines FDIO[0:127]. The error position equation is an equation having a reciprocal of the error bit as a root.

The error corrector 308 may determine the position of the error bit based on a calculation result of the error bit position detector 306. The error corrector 308 may correct the error bit by inverting a logic value of the error bit from among the 128-bit data bits according to determined error bit position information, and may output the error-corrected 128-bit data bits CDATA[0:127].

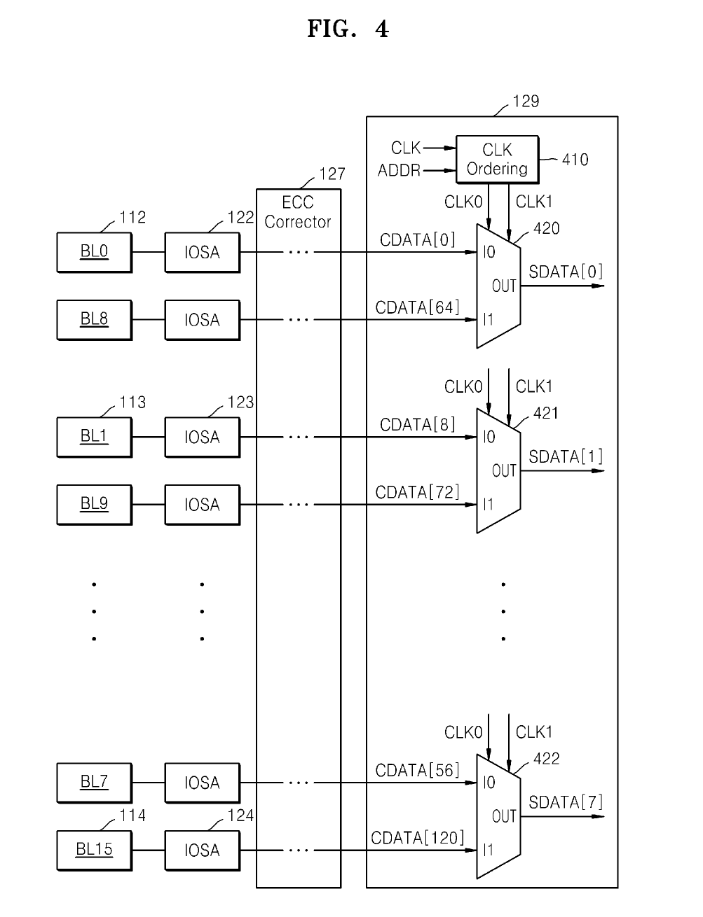

FIG. 4 is a block diagram illustrating the data serializer 129 according to some example embodiments of the inventive concepts.

Referring to FIG. 4, the data serializer 129 includes a clock ordering circuit 410, and a plurality of multiplexers 420, 421, and 422. The clock ordering circuit 410 generates a first clock signal CLK0 and a second clock signal CLK1 in response to a clock signal CLK and an address signal ADDR. The first clock signal CLK0 is a pulse signal generated in response to a rising edge of the clock signal CLK, and the second clock signal CLK1 is a pulse signal generated in response to a falling edge of the clock signal CLK.

The plurality of multiplexers 420, 421, and 422 receive the error-corrected parallel data bits CDATA[0:127] provided from the ECC corrector 127, and output the serial data bits SDATA[0:63] in response to the first and second clock signals CLK0 and CLK1. As described above with reference to FIG. 2, the serial data bits SDATA[0:63] which are fundamentally data bits corresponding to the burst length BL16 are output to 8 DQ pads DQ[0:7].

In FIG. 4, serial data bits SDATA[0:7] output to one DQ pad DQ[0] from among the 64-bit serial data bits SDATA[0:63] will be exemplarily explained. In this case, the address signal ADDR refers to an address signal related to the DQ[0] pad. The serial data bits SDATA[0:7] which are BL0, BL1, BL2, through BL15 bits having the burst length BL16 are output to the DQ[0] pad. Descriptions of the serial data bits SDATA[0:7] output to the DQ[0] pad may apply to the remaining DQ pads DQ[1:7] related to their corresponding address signals ADDR.

Each of the multiplexers 420, 421, and 422 selects and outputs data provided to a first input JO in response to the first clock signal CLK0, and selects and outputs data provided to a second input Il in response to the second clock signal CLK1.

An error-corrected data bit CDATA[0] obtained after error-correcting data read out from the BL0 cell block 112 by using the data sense amplifier 122 and the ECC corrector 127 is provided to the first input JO of the first multiplexer 420, and an error-corrected data bit CDATA[64] obtained after error-correcting data read out from the BL8 cell block by using the data sense amplifier and the ECC corrector 127 is provided to the second input I1.

The first multiplexer 420 selects and outputs the error-corrected data bit CDATA[0] of the first input I0 in response to the first clock signal CLK0, and selects and outputs the error-corrected data bit CDATA[64] of the second input I1 in response to the second clock signal CLK1. Since the error-corrected data bit CDATA[0] is output from the BL0 cell block 112, the error-corrected data bit CDATA[0] may be referred to as a data bit corresponding to a first burst length, that is, a BL0 bit. Since the error-corrected data bit CDATA[64] is output from the BL8 cell block, the error-corrected data bit CDATA[64] may be referred to as a data bit corresponding to a ninth burst length, that is, a BL8 bit. An output OUT of the first multiplexer 420 is output as a serial data bit SDATA[0].

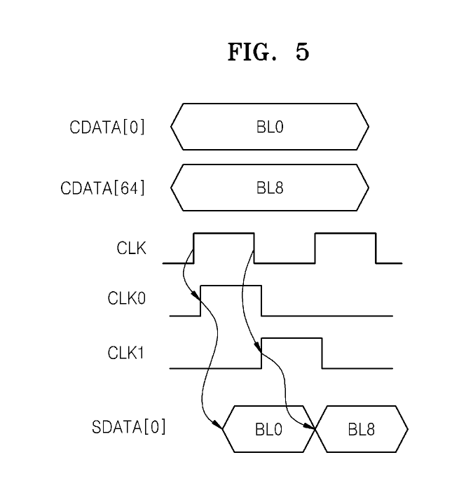

FIG. 5 is a timing diagram for explaining an operation of the first multiplexer 420, according to some example embodiments of the present inventive concepts.

Referring to FIG. 5, the data bit CDATA[0] is a BL0 bit, and the data bit CDATA[64] is a BL8 bit. The first clock signal CLK0 and the second clock signal CLK1 are generated in response to the clock signal CLK. The serial data bit SDATA[0], which is an output of the first multiplexer 420, is output as the BL0 bit that is selected in response to the first clock signal CLK0 and is output as the BL8 bit that is selected in response to the second clock signal CLK1. The serial data bit SDATA[0] is output as the BL0 bit at a rising edge of the clock signal CLK, and is output as the BL8 bit at a falling edge of the clock signal CLK. That is, the parallel data bits CDATA[0] and CDATA[64] input to the first multiplexer 420 are converted into and output as the serial data bit SDATA[0], that is, the BL0 and BL8 bits.

Referring back to FIG. 4, an error-corrected data bit CDATA[8] obtained after error-correct data read output from the BL1 cell block 113 by using the data sense amplifier 123 and the ECC corrector 127 is provided to the first input IO of the second multiplexer 421, and an error-corrected data bit CDATA[72] obtained after error-correct data output from the BL9 cell block by using the data sense amplifier and the ECC corrector 127 is provided to the second input I1. An output OUT of the second multiplexer 421 is output as a serial data bit SDATA[1].

Since the error-corrected data bit CDATA[8] is output from the BL1 cell block 113, the error-corrected data bit CDATA[8] may be referred to as a BL1 bit, and since the error-corrected data bit CDATA[72] is output from the BL9 cell block, the error-corrected data bit CDATA[72] may be referred to as a BL9 bit.

The serial data bit SDATA[1] which is the output OUT of the second multiplexer 421 is output as the BL1 bit that is selected in response to the first clock signal CLK0 and is output as the BL9 bit that is selected in response to the second clock signal CLK1. The serial data bit SDATA[1] is output as the BL1 bit at a rising edge of the clock signal CLK, and is output as the BL9 bit at a falling edge of the clock signal CLK. That is, the parallel data bits CDATA[8] and CDATA[72] input to the second multiplexer 421 are converted into and output as the serial data bit SDATA[1], that is, the BL1 and BL9 bits.

In the same manner, a multiplexer receiving data output from the BL2 cell block and data output from the BL10 cell block outputs BL2 and BL10 serial data bits in response to rising and falling edge of the clock signal CLK. A multiplexer receiving data output from the BL3 cell block and data output from the BL11 cell block outputs BL3 and BL11 serial data bits in response to rising and falling edges of the clock signal CLK. A multiplexer receiving data output from the BL4 cell block and data output from the BL12 cell block outputs BL4 and BL12 serial data bits in response to rising and falling edges of the clock signal CLK. A multiplexer receiving data output from the BL5 cell block and data output from the BL13 cell block outputs BL5 and BL13 serial data bits in response to rising and falling edges of the clock signal CLK. A multiplexer receiving data output from the BL6 cell block and data output from the BL14 cell block outputs BL6 and BL14 serial data bits in response to rising and falling edges of the clock signal CLK. The multiplexer 422 receiving data output from the BL7 cell block and data output from the BL15 cell block 114 outputs BL7 and BL15 serial data bits in response to rising and falling edges of the clock signal CLK.

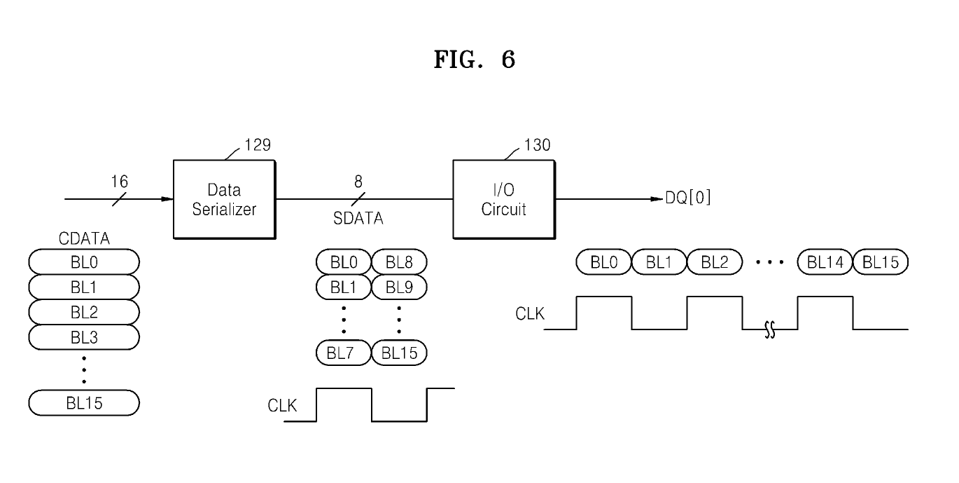

FIG. 6 is a timing diagram for explaining an operation of the data serializer 129 of FIG. 4, according to some example embodiments of the inventive concepts.

In FIG. 6, data bits corresponding to the burst length BL16 output to the DQ[0] pad through the data serializer 129 and the I/O circuit unit 130 will be explained. Error-corrected 16-bit databits CDATA that are BL0 through BL15 bits are input through 16 data lines to the data serializer 129. Serial data bits SDATA are output through 8 data lines from the data serializer 129. The BL0 through BL7 bits are output as the serial data bits SDATA at a rising edge of the clock signal CLK, and BL8 through BL15 bits are output as the serial data bits SDATA at a falling edge of the clock signal CLK. That is, bits corresponding to the burst length BL16 are divided into high-order 8 bits that are the BL0 through BL7 bits and low-order 8 bits that are the BL8 through BL15, and are output as serial data bits SDATA.

The serial data bits SDATA, that is, the high-order 8 bits BL0 through BL7 and the low-order 8 bits BL8 through BL15, output from the data serializer 129 are provided to the I/O circuit unit 130. The I/O circuit unit 130 sequentially arranges the received high-order 8 bits BL0 through BL7 and the received low-order 8 bits BL8 through BL15, and outputs the arranged bits as BL0, BL1, BL2, . . . , BL14, and BL15 bits to the DQ[0] pad.

Along with the data bits corresponding to the burst length BL16 output to the DQ[0] pad, data bits corresponding to the burst length BL16 are output as BL0, BL1, BL2, . . . , BL14, and BL15 bits to each of the DQ[1] through DQ[7] pads. Accordingly, since 128-bit parallel data bits read out from the BL0 through BL15 cell blocks 112 through 114 of FIG. 2 are error-corrected and then are output to the DQ[0] through DQ[7] pads, the semiconductor memory device 100 stably outputs data with no error.

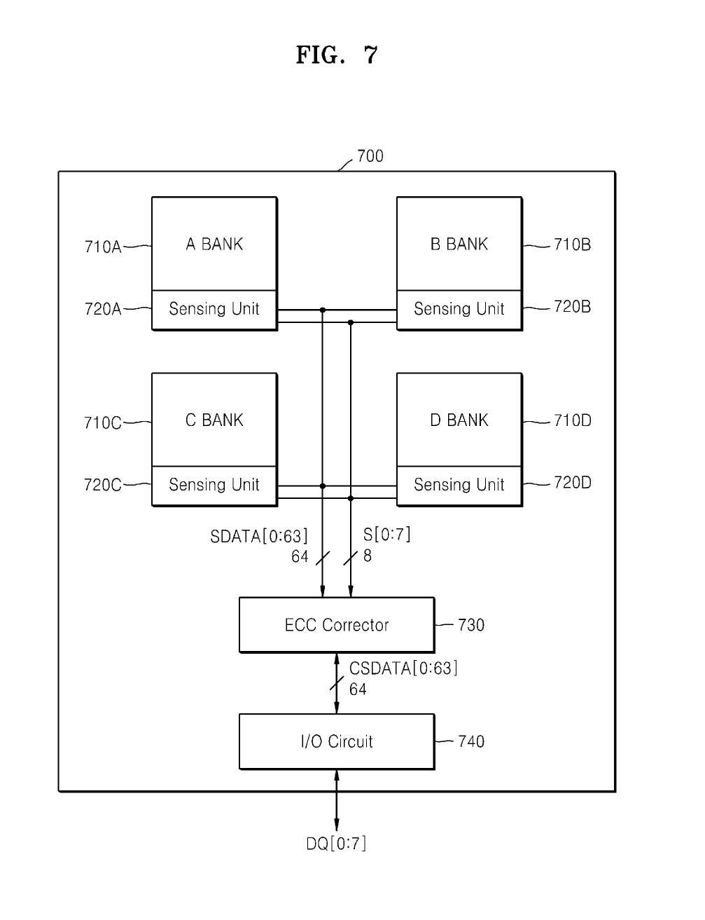

FIG. 7 is a block diagram illustrating a semiconductor memory device 700 according to some example embodiments of the inventive concepts.

Referring to FIG. 7, the semiconductor memory device 700 includes a plurality of banks, for example, A through D banks 710A through 710D, data sensing units 720A through 720D respectively connected to the A through D banks 710A through 710D, an ECC corrector 730, and an I/O circuit unit 740. The semiconductor memory device 700 is different from the semiconductor memory device 100 of FIG. 1 in that the ECC corrector 730 is disposed adjacent to the I/O circuit unit 740. Since the ECC corrector 730 is shared by the A through D banks 710A through 710D, the semiconductor memory device 700 may reduce a chip size.

Each of the A through D banks 710A through 710D includes a plurality of memory cells. The data sensing units 720A through 720D respectively sense and amplify parallel data bits read out from the memory cells of the A through D banks 710A through 710D, and generates syndrome data S[0:7] for performing error detection on the sensed and amplified parallel data bits. Also, the data sensing units 720A through 720D convert the parallel data bits of the A through D banks 710A through 710D into serial data bits SDATA[0:63] and output the serial data bits SDATA[0:63].

The ECC corrector 730 is shared by the A through D banks 710A through 710D. The ECC corrector 730 receives the syndrome data S[0:7] and the serial data bits SDATA[0:63] output from the A through D banks 710A through 710D. The ECC corrector 730 error-corrects the serial data bits SDATA[0:63] by using the syndrome data S[0:7] and outputs error-corrected serial data bits CSDATA[0:63].

The I/O circuit unit 740 receives the error-corrected serial data bits CSDATA[0:63] output from the ECC corrector 730, sequentially arranges the received error-corrected serial data bits CSDATA[0:63] as data bits corresponding to the burst length BL, and outputs the sequentially arranged data bits to data I/O pads DQ[0:7]. The ECC corrector 730 is disposed adjacent to the I/O circuit unit 740.

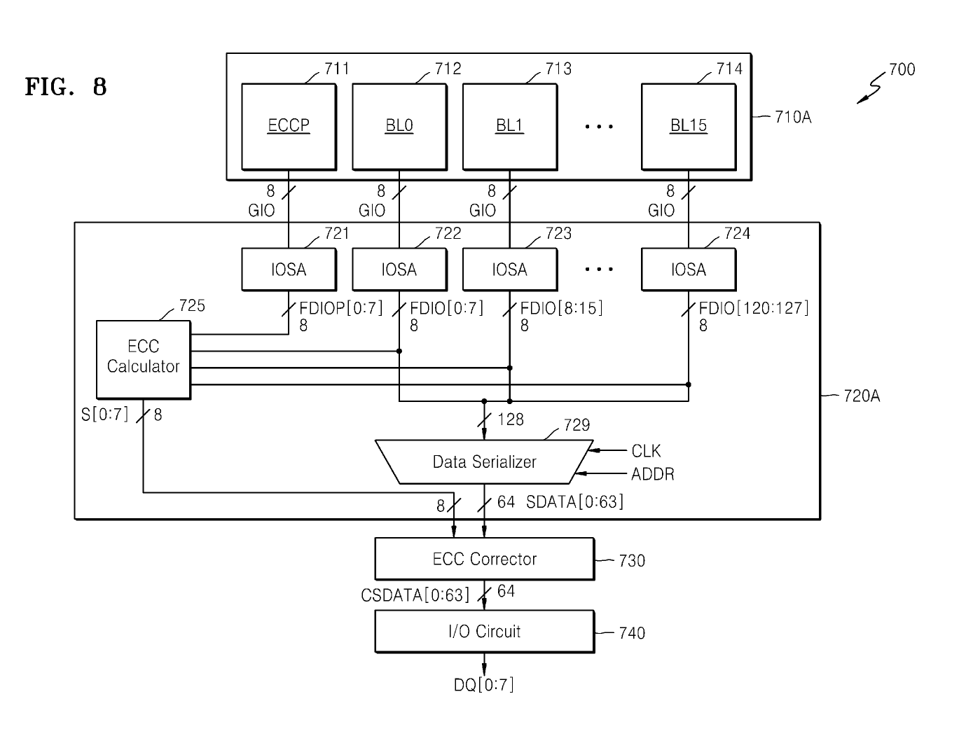

FIG. 8 is a block diagram illustrating a bank and a data sensing unit of the semiconductor memory device 700 of FIG. 7, according to some example embodiments of the inventive concepts. In FIG. 8, the A bank 710A, the data sensing unit 720A connected to the A bank 710A, the ECC corrector 730, and the I/O circuit unit 740 of FIG. 7 will be explained. Descriptions of the A bank 710A and the data sensing unit 720A may apply to the remaining B through D banks 710B through 710D and the data sensing units 720B through 720D.

Referring to FIG. 8, the A bank 710A may include an ECCP cell block 711, and BL0 through BL15 cell blocks 712 through 714, like the A bank 110A of FIG. 2. Each of the ECCP cell block 711 and the BL0 through BL15 cell blocks 712 through 714 is connected to 8 first data lines GIO. The number of the first data lines GIO connected to the BL0 through BL15 cell blocks 712 through 714 is 128, and the number of the first data lines GIO connected to the ECCP cell block 711 is 8.

The first data lines GIO connected to each of the ECCP cell block 711 and the BL0 through BL15 cell blocks 712 through 714 are connected to the data sensing unit 720A. The data sensing unit 720A senses and amplifies data read out from the ECCP cell block 711 and the BL0 through BL15 cell blocks 712 through 714 transmitted through the first data lines GIO, and calculates the syndrome data S[0:7] for performing error detection on the sensed and amplified data. Also, the data sensing unit 720A converts the sensed and amplified data of the BL0 through BL15 cell blocks 712 through 714 into serial data bits SDATA[0:63] and outputs the serial data bits SDATA[0:63].

The data sensing unit 720A includes data line sense amplifiers 721 through 724, an ECC calculator 725, and a data serializer 729. The data sensing unit 720A does not include an ECC corrector, unlike the data sensing unit 120A of FIG. 2. Instead, the ECC corrector 730 is disposed adjacent to the I/O circuit unit 740.

The data line sense amplifiers 721 through 724 respectively sense and amplify data read out from the ECCP cell block 711 and the BL0 through BL15 cell blocks 712 through 714 transmitted through the first data lines GIO. The data read out from the ECCP cell block 711 is sensed and amplified by the data line sense amplifier 721, and is transmitted to a second data line FDIOP. The data read out from the BL0 through BL15 cell blocks 712 through 714 is transmitted to second data lines FDIO through the data line sense amplifiers 722 through 724. The sensed and amplified data transmitted to the second data lines FDIOP and FDIO is provided to the ECC calculator 725 and the data serializer 729.

The ECC calculator 725 performs functions related to error detection on the data transmitted to the second data lines FDIOP and FDIO. The ECC calculator 725 may output the syndrome data S[0:7] for detecting an error bit from among data on the second data lines FDIO[0:127] by using data transmitted through the second data lines FDIO[0:127] from the BL0 through BL15 cell blocks 712 through 714 and parity bits transmitted through the second data line FDIOP[0:7] from the ECCP cell block 711. The ECC calculator 725 may receive 128-bit read data bits transmitted through the second data lines FDIO[0:127] and 8-bit parity bits transmitted to the second data line FDIOP[0:7], and may generate the syndrome data S[0:7] by using an XOR array operation.

The 128-bit read data bits of the BL0 through BL15 cell blocks 712 and 714 which are sensed and amplified by the data line sense amplifiers 722 through 724 are provided to the data serializer 729 through the second data lines FDIO[0:127]. The data serializer 729 receives in parallel the 128-bit read data bits in response to a clock signal CLK and an address signal ADDR, converts the received 128-bit read data bits into 64-bit serial data bits SDATA[0:63], and outputs the 64-bit serial data bits SDATA[0:63].

The 64-bit serial data bits SDATA[0:63] output from the data serializer 729 may be finally output to the DQ pads DQ[0:7] related to the address signal ADDR. The 128-bit read data bits received by the data serializer 729 are data bits corresponding to the burst length BL16 output to the DQ pads DQ[0:7].

The data serializer 729 may divide data bits corresponding to the burst length BL16 to be output to the DQ pads DQ[0:7] into high-order 8 bits that are BL0 through BL7 bits and low-order 8 bits that are BL8 through BL15 bits, and may output the high-order and low-order bits as serial data bits SDATA[0:63]. The data serializer 729 outputs the high-order 8 bits that are the BL0 through BL7 bits to be output to the DQ pads DQ[0:7] as serial data bits SDATA at a rising edge of the clock signal CLK, and outputs the low-order 8 bits that are the BL8 through BL15 bits to be output to the DQ pads DQ[0:7] as SDATA serial data bits at a falling edge of the clock signal CLK.

The 64-bit serial data bits SDATA[0:63] of the data serializer 729 and the syndrome data S[0:7] of the ECC calculator 725 are provided to the ECC corrector 730. The ECC corrector 730 may calculate a position of an error bit from among the high-order 8 bits that are the BL0 through BL7 bits and the low-order 8 bits that are the BL8 through BL15 bits of the 64-bit serial data bits SDATA[0:63] by using the syndrome data S[0:7]. The ECC corrector 730 may correct the error bit by inverting a logic value of the error bit from among the high-order 8 bits that are the BL0 through BL7 bits and the low-order 8 bits that are the BL8 through BL15 bits of the 64-bit serial data bits SDATA[0:63] according to error bit position information.

The ECC corrector 730 may correct the error bit by inverting a logic value of the error bit at a time when the high-order 8 bits that are the BL0 through BL7 bits of the 64-bit serial data bits SDATA[0:63] are output in response to a rising edge of the clock signal CLK, or at a time when the low-order 8 bits that are the BL8 through BL15 bits are output. Alternatively, when the ECC corrector 730 includes a latch unit that latches the high-order 8 bits that are the BL0 through BL7 bits and the low-order 8 bits that are the BL8 through BL15 bits of the 64-bit serial data bits SDATA[0:63] in the data serializer 729, the error bit may be corrected by inverting a logic value of the latch unit that latches the error bit.

An operation of the ECC corrector 730 is shorter in time than an operation performed by the ECC calculator 725 that receives 128-bit read data bits and 8-bit parity bits to detect an error bit and generates the syndrome data S[0:7] by using an XOR array operation. Even when an error correction operation of the ECC corrector 730 is performed on the 64-bit serial data bits SDATA[0:63] output from the data serializer 729, the semiconductor memory device 700 is expected to have the same data access time tAA as the first semiconductor memory device 100 of FIG. 1. Accordingly, the semiconductor memory device 700 has no timing overhead even when the ECC calculator 725 and the ECC corrector 730 are separately disposed.

The error-corrected data bits CSDATA[0:63] output from the ECC corrector 730 are provided to the I/O circuit unit 740. The I/O circuit unit 740 receives the error-corrected data bits CSDATA[0:63], and outputs data bits corresponding to the burst length BL16 to the DQ pads DQ[0:7]. Accordingly, the semiconductor memory device 700 stably outputs data with no error.

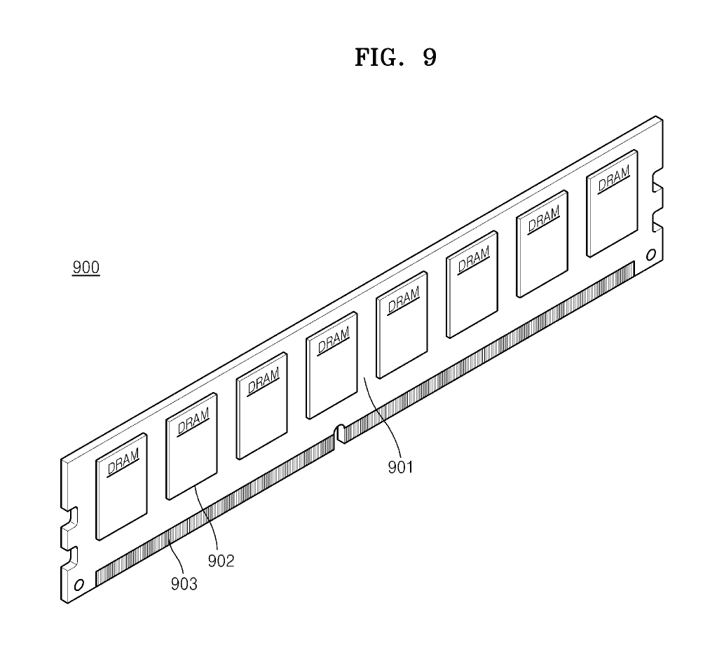

FIGS. 9 through 11 are perspective views illustrating memory modules each including a dynamic random access memory (DRAM) including an ECC circuit that is separately disposed, according to some example embodiments of the inventive concepts.

Referring to FIG. 9, a memory module 900 includes a printed circuit board (PCB) 901, a plurality of DRAM chips 902, and a connector 903. The plurality of DRAM chips 902 may be coupled to a top surface and a bottom surface of the PCB 901. The connector 903 is electrically connected to the plurality of DRAM chips 902 through conductive lines Also, the connector 903 may be connected to a slot of an external host.

Each of the DRAM chips 902 may include a plurality of banks, data sensing units respectively connected to the banks, and an I/O circuit unit. Each of the data sensing units may include data sense amplifiers that sense and amplify parallel data bits read out from memory cells of each of the banks, an ECC calculator that generates syndrome data for detecting an error bit from among the parallel data bits, an ECC corrector that corrects the error bit from among the parallel data bits by using the syndrome data and outputs error-corrected parallel data bits, and a data serializer that receives and converts the error-corrected parallel data bits into serial data bits and outputs the serial data bits to the I/O circuit unit. The ECC calculator and the ECC corrector may be separated from each other in the data sensing unit connected to each of the banks, and the ECC calculator may be disposed adjacent to the data line sense amplifiers.

Each of the DRAM chips 902 may include a plurality of banks, data sensing units respectively connected to the banks, an ECC corrector, and an I/O circuit unit. Each of the data sensing units may include an ECC calculator that generates syndrome data for detecting an error bit from among parallel data bits read out from memory cells of each of the banks, and a data serializer that receives and converts the parallel data bits into serial data bits. An ECC corrector may correct an error bit from among the serial data bits by using the syndrome data, and may output the error-corrected serial data bits to the I/O circuit unit. The I/O circuit unit may output the error-corrected serial data bits corresponding to a burst length to the data I/O pad DQ. The ECC calculator may be disposed in the data sensing unit connected to each of the banks, and the ECC corrector may be shared by the banks and may be disposed adjacent to the I/O circuit unit.

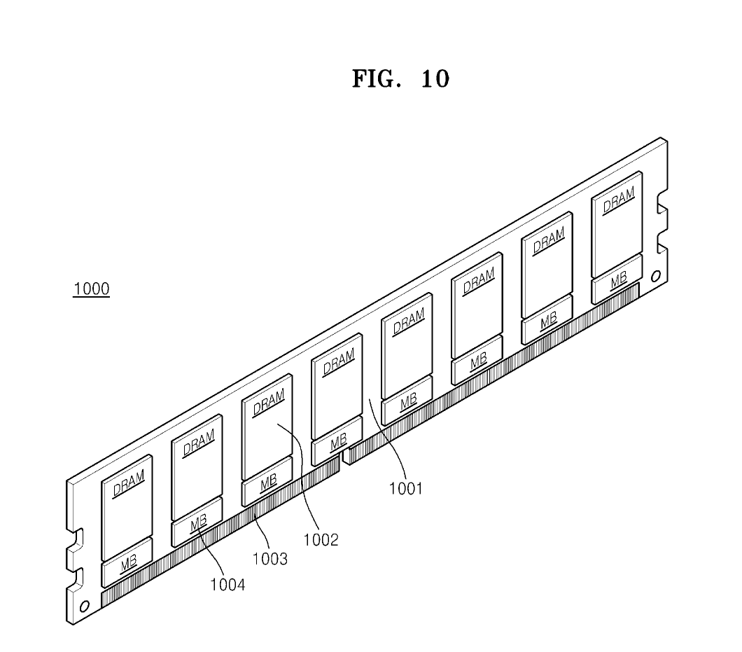

Referring to FIG. 10, a memory module 1000 includes a PCB 1001, a plurality of DRAM chips 1002, a connector 1003, and a plurality of buffer chips 1004. The plurality of buffer chips 1004 may be disposed between the DRAM chips 1002 and the connector 1003. The DRAM chips 1002 and the buffer chips 1004 may be provided on a top surface and a bottom surface of the PCB 1001. The DRAM chips 1002 and the buffer chips 1004 provided on the top surface and the bottom surface of the PCB 1001 may be connected through a plurality of via holes.

Each of the DRAM chips 1002 may include a plurality of banks, data sensing units respectively connected to the banks, and an I/O circuit unit. Each of the data sensing units may include data line sense amplifiers that sense and amplify parallel data bits read out from memory cells of each of the banks, an ECC calculator that generates syndrome data for detecting an error bit from among the parallel data bits, an ECC corrector that corrects the error bit from among the parallel data bits by using the syndrome data and outputs error-corrected parallel data bits, and a data serializer that receives and converts the error-corrected parallel data bits into serial data bits and outputs the serial data bits to the I/O circuit unit. The ECC calculator and the ECC corrector may be separated from each other in the data sensing unit connected to each of the banks, and the ECC calculator may be disposed adjacent to the data line sense amplifiers.

Each of the DRAM chips 1002 may include a plurality of banks, data sensing units respectively connected to the banks, an ECC corrector, and an I/O circuit unit. Each of the data sensing units may include an ECC calculator that generates syndrome data for detecting an error bit from among parallel data bits output from memory cells of each of the banks, and a data serializer that receives and converts the parallel data bits into serial data bits. The ECC corrector may correct an error bit from among the serial data bits by using the syndrome data, and may output the error-corrected serial data bits to the I/O circuit unit. The I/O circuit unit may output the error-corrected serial data bits corresponding to a burst length to the data I/O pad DQ. The ECC calculator may be disposed in the data sensing unit connected to each of the banks, and the ECC corrector may be shared by the banks and may be disposed adjacent to the I/O circuit unit.

The buffer chips 1004 may store results after obtained by testing characteristics of the DRAM chips 1002 connected to the buffer chips 1004. The buffer chips 1004 reduce the effect of a weak cell or a weak page on operations of the DRAM chips 1002 by managing the operations of the DRAM chips 1002 by using information about the stored characteristics. For example, the buffer chips 1004 may include storage units therein and may remedy a weak cell or a weak page of the DRAM chips 1002.

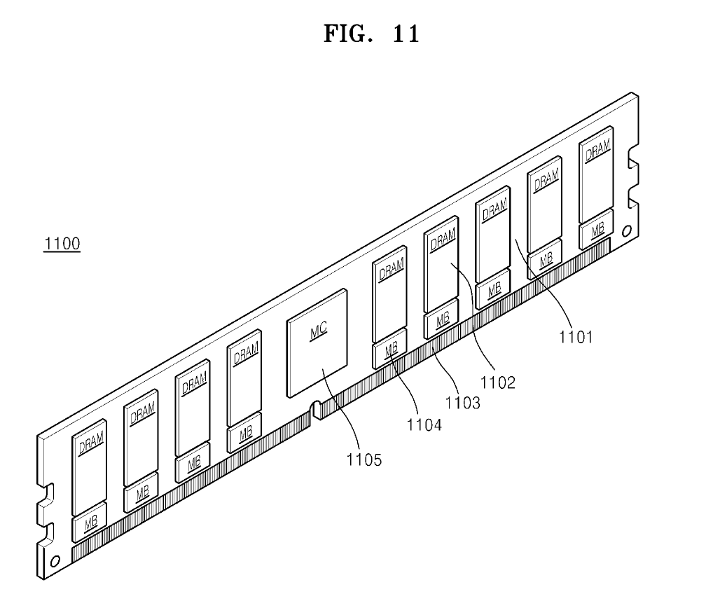

Referring to FIG. 11, a memory module 1100 includes a PCB 1101, a plurality of DRAM chips 1102, a connector 1103, a plurality of buffer chips 1104, and a controller 1105. The controller 1105 communicates with the DRAM chips 1102 and the buffer chips 1104, and controls an operation mode of the DRAM chips 1102. The controller 1105 may control various functions, characteristics, and modes by using a mode register of the DRAM chips 1102.

Each of the DRAM chips 1102 may include a plurality of banks, data sensing units respectively connected to the banks, and an I/O circuit unit. Each of the data sensing units may include data line sense amplifiers that sense and amplify parallel data bits read out from memory cells of each of the banks, an ECC calculator that generates syndrome data for detecting an error bit from among the parallel data bits, an ECC corrector that corrects the error bit from among the parallel data bits by using the syndrome data and outputs the error-corrected parallel data bits, and a data serializer that receives and converts the error-corrected parallel data bits into serial data bits and outputs the serial data bits to the I/O circuit unit. The ECC calculator and the ECC corrector may be separated from each other in the data sensing unit connected to each of the banks, and the ECC calculator may be disposed adjacent to the data line sense amplifiers.

Each of the DRAM chips 1102 may include a plurality of banks, data sensing units respectively connected to the banks, an ECC corrector, and an I/O circuit unit. Each of the data sensing units may include an ECC calculator that generates syndrome data for detecting an error bit from among parallel data bits read out from memory cells of each of the banks, and a data serializer that receives and converts the parallel data bits into serial data bits. The ECC corrector may correct an error bit from among the serial data bits by using the syndrome data and may output the error-corrected serial data bits to the I/O circuit unit. The I/O circuit unit may output the error-corrected serial data bits corresponding to a burst length to the data I/O pad DQ. The ECC calculator may be disposed in the data sensing unit connected to each of the banks, and the ECC corrector may be shared by the banks and may be disposed adjacent to the I/O circuit unit.

Each of the memory modules 900, 1000, and 1100 may be embodied as any of memory modules such as a single in-line memory module (SIMM), a dual in-line memory module (DIMM), a small-outline DIMM (SO-DIMM), a unbuffered DIMM (UDIMM), a fully-buffered DIMM (FBDIMM), a rank-buffered DIMM (RBDIMM), a load-reduced DIMM (LRDIMM), a mini-DIMM, and a micro-DIMM.

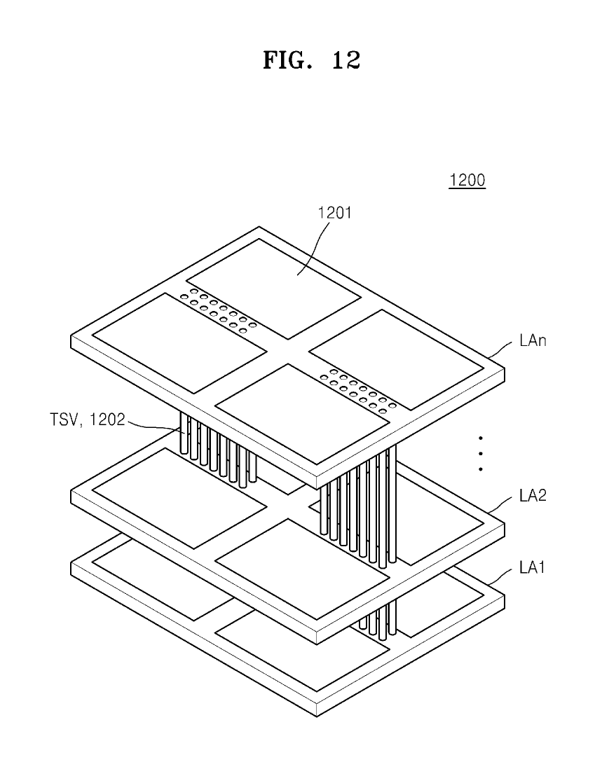

FIG. 12 is a perspective view illustrating a semiconductor device 1200 having a stacked structure including DRAM semiconductor layers each including an ECC circuit that is separately disposed, according to some example embodiments of the inventive concepts.

Referring to FIG. 12, the semiconductor device 1200 may include a plurality of DRAM semiconductor layers LA1 through LAn. Each of the semiconductor layers LA1 through LAn may be a memory chip including a memory cell array 1201 including DRAM cells, and some of the semiconductor layers LA1 through LAn may be master chips that interface with an external controller and the other semiconductor layers may be slave chips that store data. In FIG. 12, the semiconductor layer LA1 that is a lowermost semiconductor layer may be a master chip, and the other semiconductor layers LA2 through LAn may be slave chips.

The plurality of semiconductor layers LA1 through LAn may transmit/receive a signal through through-silicon vias (TSV) 1202, and the master chip LA1 may communicate with an external memory controller (not shown) through a conductive unit (not shown) formed on an outer surface thereof

Also, a signal may be transmitted between the semiconductor layers LA1 through LAn by using optical I/O connection, for example, a radiative method using radio frequency (RF) waves or ultrasonic waves, an inductive coupling method using magnetic induction, or a non-radiative method using resonance of a magnetic field.

The radiative method is a method that wirelessly transmits a signal by using an antenna such as a monopole antenna or a planar inverted-F antenna (PIFA). Radiation occurs as electric fields or magnetic fields that varies over time affect each other, and when there are antennas using the same frequency, a signal may be received according to polarization characteristics of incident waves. The inductive coupling method is a method that generates a strong magnetic field in one direction by winding a coil several times, and causes coupling by disposing a coil that resonates at a frequency similar to that of the wound coil to be adjacent to the wound coil. The non-radiative method is a method that uses evanescent wave coupling to move electromagnetic waves between two media resonating at the same frequency through a near electromagnetic field.

Each of the semiconductor layers LA1 through LAn may include a plurality of banks, data sensing units respectively connected to the banks, and an I/O circuit unit. Each of the data sensing units may include data line sense amplifiers that sense and amplify parallel data bits read out from memory cells of each of the banks, an ECC calculator that generates syndrome data for detecting an error bit from among the parallel data bits, an ECC corrector that corrects the error bit from among the parallel data bits by using the syndrome data and outputs the error-corrected parallel data bits, and a data serializer that receives and converts the error-corrected parallel data bits into serial data bits and outputs the serial data bits to the I/O circuit unit. The ECC calculator and the ECC corrector may be separated from each other in the data sensing unit connected to each of the banks, and the ECC calculator may be disposed adjacent to the data line sense amplifiers.

Each of the semiconductor layers LA1 through LAn may include a plurality of banks, data sensing units respectively connected to the banks, an ECC corrector, and an I/O circuit unit. Each of the data sensing units may include an ECC calculator that generates syndrome data for detecting an error bit from among parallel data bits read out from memory cells of each of the banks, and a data serializer that receives and converts the parallel data bits into serial data bits. The ECC corrector may correct an error bit from among the serial data bits by using the syndrome data and may output the error-corrected serial data bits to the I/O circuit unit. The I/O circuit unit may output the error-corrected serial data bits corresponding to a burst length to the data I/O pad DQ. The ECC calculator may be disposed in the data sensing unit connected to each of the banks, and the ECC corrector may be shared by the banks and may be disposed adjacent to the I/O circuit unit.

Each of the DRAM chips in the modules 900, 1000, and 1100 of FIGS. 9 through 11 may include the plurality of DRAM semiconductor layers LA1 through LAn.

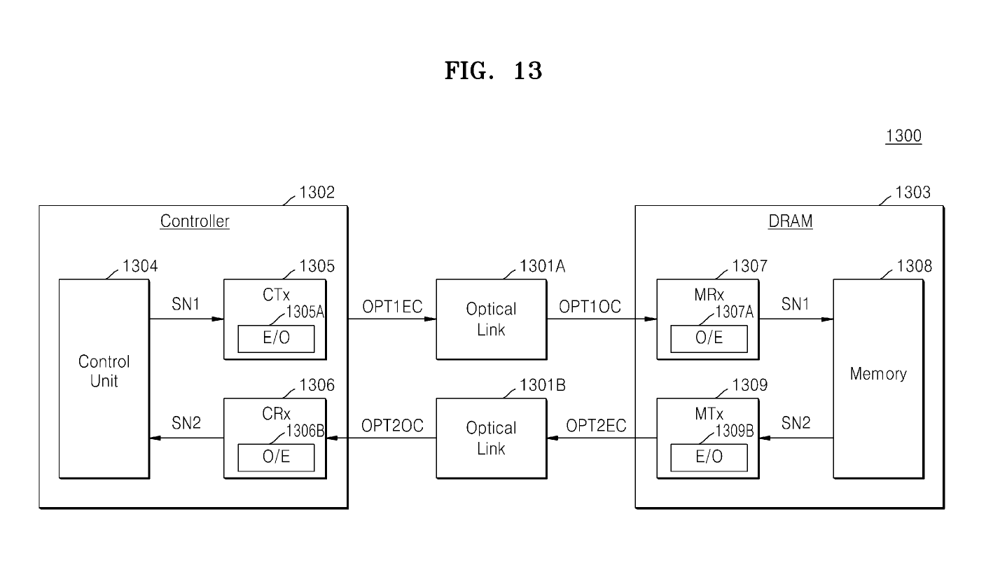

FIG. 13 is a block diagram illustrating a memory system 1300 including a DRAM 1303 including an ECC circuit that is separately disposed, according to some example embodiments of the inventive concepts.

Referring to FIG. 13, the memory system 1300 includes optical interconnection devices 1301A and 1301B, a controller 1302, and the DRAM 1303. The optical interconnection devices 1301A and 1301B interconnect the controller 1302 and the DRAM 1303. The controller 1302 includes a control unit 1304, a first transmission unit 1305, and a first receiving unit 1306. The control unit 1304 transmits a first electrical signal SN1 to the first transmission unit 1305. The first electrical signal SN1 may include command signals, clocking signals, address signals, or write data to be transmitted to the DRAM 1303.

The first transmission unit 1305 includes a first optical modulator 1305A. The first optical modulator 1305A converts the first electrical signal SN1 into a first optical transmission signal OPT1EC and transmits the first optical transmission signal OPT1EC to the optical interconnection device 1301A. The first optical transmission signal OPT1EC is transmitted through the optical interconnection device 1301A by using serial communication. The first receiving unit 1306 includes a first optical demodulator 1306B. The first optical demodulator 1306B converts a second optical receiving signal OPT2OC received from the optical interconnection device 1301B into a second electrical signal SN2 and transmits the second electrical signal SN2 to the control unit 1304.

The DRAM 1303 includes a second receiving unit 1307, a memory area 1308 including a memory cell array, and a second transmission unit 1309. The memory area 1308 may include a plurality of banks, data sensing units respectively connected to the banks, and an I/O circuit unit. Each of the data sensing units may include data line sense amplifiers that sense and amplify parallel data bits read out from memory cells of each of the banks, an ECC calculator that generates syndrome data for detecting an error bit from among the parallel data bits, an ECC corrector that corrects the error bit from among the parallel data bits by using the syndrome data and outputs the error-corrected parallel data bits, and a data serializer that receives and converts the error-corrected parallel data bits into serial data bits and outputs the serial data bits to the I/O circuit unit. The ECC calculator and the ECC corrector may be separated from each other in the data sensing unit connected to each of the banks, and the ECC calculator may be disposed adjacent to the data line sense amplifiers.

The memory area 1308 may include a plurality of banks, data sensing units respectively connected to the banks, an ECC corrector, and an I/O circuit unit. Each of the data sensing units may include an ECC calculator that generates syndrome data for detecting an error bit from among parallel data bits read out from memory cells of each of the banks, and a data serializer that receives and converts the parallel data bits into serial data bits. The ECC corrector may correct an error bit from among the serial data bits by using the syndrome data and output the error-corrected serial data bits to the I/O circuit unit. The I/O circuit unit may output the error-corrected serial data bits corresponding to a burst length to the data I/O pad DQ. The ECC calculator may be disposed in the data sensing unit connected to each of the banks, and the ECC corrector may be shared by the banks and may be disposed adjacent to the I/O circuit unit.

The second receiving unit 1307 includes a second optical demodulator 1307A. The second optical demodulator 1307A converts a first optical receiving signal OPT1OC output from the optical interconnection device 1301A into a first electrical signal SN1 and transmits the first electrical signal SN1 to the memory area 1308.

The memory area 1308 writes data to a memory cell in response to the first electrical signal SN1, or reads data therefrom and transmits the data as a second electrical signal SN2 to the second transmission unit 1309. The second electrical signal SN2 may include a clocking signal, read data, or the like transmitted to the controller 1302. The second transmission unit 1309 includes a second optical demodulator 1309B. The second optical demodulator 1309B converts the second electrical signal SN2 into a second optical transmission signal OPT2EC and transmits the second optical data signal OPT2EC to the optical interconnection device 1301B. The second optical transmission signal OPT2EC is transmitted through the optical interconnection device 1301B by using serial communication.

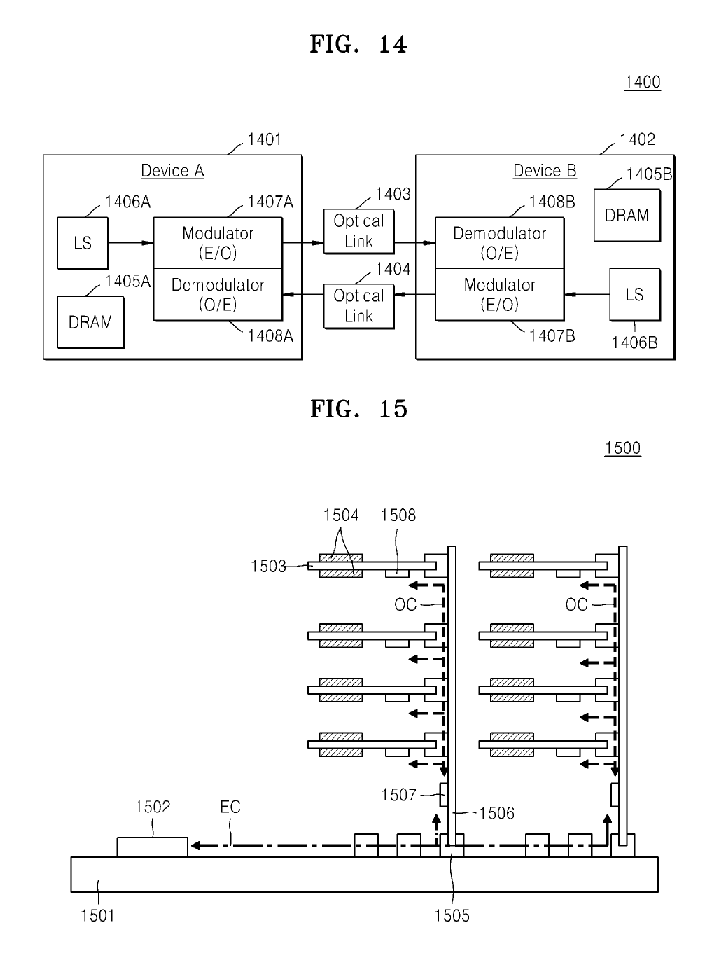

FIG. 14 is a block diagram illustrating a data processing system 1400 including a DRAM including an ECC circuit that is separately disposed, according to some example embodiments of the inventive concepts.

Referring to FIG. 14, the data processing system 1400 includes a first device 1401, a second device 1402, and a plurality of optical interconnection devices 1403 and 1404. The first device 1401 and the second device 1402 may communicate an optical signal by using serial communication.

The first device 1401 may include a DRAM 1405A, a first light source 1406A, a first optical modulator 1407A that performs an electric-to-optical (E/O) conversion operation, and a first optical demodulator 1408A that performs an optical-to-electric (0/E) conversion operation. The second device 1402 includes a DRAM 1405B, a second light source 1406B, a second optical modulator 1407B, and a second optical demodulator 1408B.

Each of the DRAMs 1405A and 1405B may include a plurality of banks, data sensing units respectively connected to the banks, and an I/O circuit unit. Each of the data sensing units may include data line sense amplifiers that sense and amplify parallel data bits read out from memory cells of each of the banks, an ECC calculator that generates syndrome data for detecting an error bit from among the parallel data bits, an ECC corrector that corrects the error bit from among the parallel data bits by using the syndrome data and outputs the error-corrected parallel data bits, and a data serializer that receives and converts the error-corrected parallel data bits into serial data bits and outputs the serial data bits to the I/O circuit unit. The ECC calculator and the ECC corrector may be separated from each other in the data sensing unit connected to each of the banks, and the ECC calculator may be disposed adjacent to the data line sense amplifiers.

Each of the DRAMs 1405A and 1405B may include a plurality of banks, data sensing units respectively connected to the banks, an ECC corrector, and an I/O circuit unit. Each of the data sensing units may include an ECC calculator that generates syndrome data for detecting an error bit from among parallel data bits read out from memory cells of each of the banks, and a data serializer that receives and converts the parallel data bits into serial data bits. The ECC corrector may correct an error bit from among the serial data bits by using the syndrome data and may output the error-corrected serial data bits to the I/O circuit unit. The I/O circuit unit may output the error-corrected serial data bits corresponding to a burst length to the data I/O pad DQ. The ECC calculator may be disposed in the data sensing unit connected to each of the banks, and the ECC corrector may be shared by the banks and may be disposed adjacent to the I/O circuit unit.

Each of the first and second light sources 1406A and 1406B outputs an optical signal having a continuous waveform. Each of the first and second light sources 1406A and 1406B may be a distributed feedback laser diode (DFB-LD) that is a multi-wavelength light source or a Fabry Perot laser diode (FP-LD).

The first optical modulator 1407A converts transmission data into an optical transmission signal and transmits the optical transmission signal to the optical interconnection device 1403. The first optical modulator 1407A may modulate a wavelength of an optical signal received by the first light source 1406A according to the transmission data. The first optical demodulator 1408A receives and demodulates an optical signal output from the second optical modulator 1407B through the optical interconnection device 1404 into an electrical signal and outputs the electrical signal.

The second optical modulator 1407B converts transmission data of the second device 1402 into an optical transmission signal and transmits the optical transmission signal to the optical interconnection device 1404. The second optical modulator 1407B may modulate a wavelength of an optical signal received by the second light source 1406B according to the transmission data. The second optical demodulator 1408B receives and demodulates an optical signal output from the first optical modulator 1407A of the first device 1401 through the optical interconnection device 1403 into an electrical signal and outputs the electrical signal.

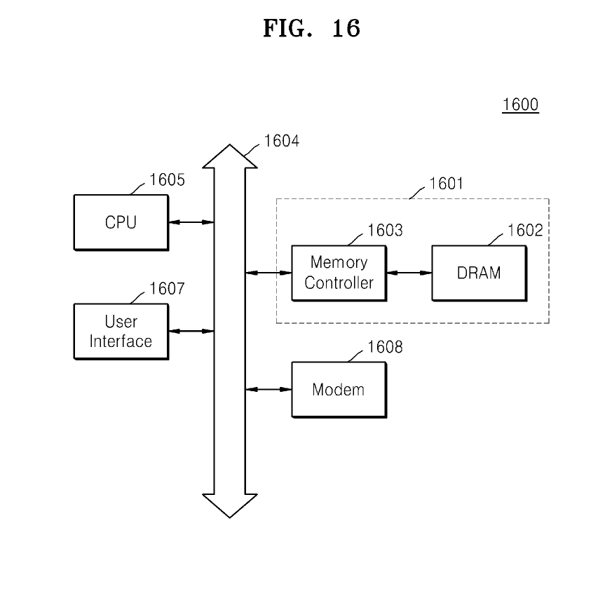

FIG. 15 is a view illustrating a server system 1500 including a DRAM including an ECC circuit that is separately disposed, according to some example embodiments of the inventive concepts.

Referring to FIG. 15, the server system 1500 includes a memory controller 1502 and a plurality of memory modules 1503. Each of the memory modules 1503 may include a plurality of DRAM chips 1504.

Each of the DRAM chips 1504 may include a plurality of banks, data sensing units respectively connected to the banks, and an I/O circuit unit. Each of the data sensing units may include data line sense amplifiers that sense and amplify parallel data bits read out from memory cells of each of the banks, an ECC calculator that generates syndrome data for detecting an error bit from among the parallel data bits, an ECC corrector that corrects the error bit from among the parallel data bits by using the syndrome data and outputs the error-corrected parallel data bits, and a data serializer that receives and converts the error-corrected parallel data bits into serial data bits and outputs the serial data bits to the I/O circuit unit. The ECC calculator and the ECC corrector may be separated from each other in the data sensing unit connected to each of the banks, and the ECC calculator may be disposed adjacent to the data line sense amplifiers.

Each of the DRAM chips 1504 may include a plurality of banks, data sensing units respectively connected to the banks, an ECC corrector, and an I/O circuit unit. Each of the data sensing units may include an ECC calculator that generates syndrome data for detecting an error bit from among parallel data bits read out from memory cells of each of the banks and a data serializer that receives and converts the parallel data bits into serial data bits. The ECC corrector may error an error bit from among the serial data bits by using the syndrome data and may output the error-corrected serial data bits to the I/O circuit unit. The I/O circuit unit may output the error-corrected serial data bits corresponding to a burst length to the data I/O pad DQ. The ECC calculator may be disposed in the data sensing unit connected to each of the banks, and the ECC corrector may be shared by the banks and may be disposed adjacent to the I/O circuit unit.

The server system 1500 may have a structure in which a second circuit board 1506 is inserted into sockets 1505 of a first circuit board 1501. The server system 1500 may have a channel structure in which one second circuit board 1506 is connected to the first circuit board 1501 in units of signal channels. However, the present embodiment is not limited thereto, and the server system 1500 may have any of various other structures.

A signal may be transmitted between the memory modules 1503 by using optical I/O connection. For the optical I/O connection, the server system 1500 may further include an E/O conversion unit 1507, and each of the memory modules 1503 may further include an 0/E conversion unit 1508.

The memory controller 1502 is connected to the E/O conversion unit 1507 through an electrical channel EC. The E/O conversion unit 1507 converts an electrical signal received from the memory controller 1502 through the electrical channel EC into an optical signal and transmits the optical signal to an optical channel OC. Also, the E/O conversion unit 1507 converts an optical signal received from the optical channel OC into an electrical signal and transmits the electrical signal to the electrical channel EC.

The memory modules 1503 are connected to the E/O conversion unit 1507 through the optical channel OC. An optical signal applied to each of the memory modules 1503 may be converted into an electrical signal by the O/E conversion unit 1508 and may be transmitted to the DRAM chips 1504. The server system 1500 including the memory modules 1503 may support a high storage capacity and high-speed processing.

FIG. 16 is a block diagram illustrating a computer system 1600 on which a DRAM including an ECC circuit that is separately disposed is mounted, according to some example embodiments of the inventive concepts.

Referring to FIG. 16, the computer system 1600 may be mounted on a mobile device or a desktop computer. The computer system 1600 may include a DRAM memory system 1601, a central processing unit (CPU) 1605, a user interface 1607, and a modem 1608 such as a baseband chipset which are electrically connected via a system bus 1604. The computer system 1600 may further include an application chipset, a camera image processor (CIS), or an I/O device.

The user interface 1607 may be an interface for transmitting data to a communication network or receiving data from the communication network. The user interface 1607 may be a wired or wireless user interface, and may include an antenna or a wired/wireless transceiver. Data provided through the user interface 1607 or the modem 1608 or processed by the CPU 1605 may be stored in the DRAM memory system 1601.

The DRAM memory system 1601 may include a DRAM 1602 and a memory controller 1603. Data processed by the CPU 1605 or data input from the outside is stored in the DRAM 1602. The DRAM 1602 may include a plurality of banks, data sensing units respectively connected to the banks, and an I/O circuit unit. Each of the data sensing units may include data line sense amplifiers that sense and amplify parallel data bits read out from memory cells of each of the banks, an ECC calculator that generates syndrome data for detecting an error bit from among the parallel data bits, an ECC corrector that corrects the error bit from among the parallel data bits by using the syndrome data and outputs the error-corrected parallel data bits, and a data serializer that receives and converts the error-corrected parallel data bits into serial data bits and outputs the serial data bits to the I/O circuit unit. The ECC calculator and the ECC corrector may be separated from each other in the data sensing unit connected to each of the banks, and the ECC calculator may be disposed adjacent to the data line sense amplifiers.

The DRAM 1602 may include a plurality of banks, data sensing units respectively connected to the banks, an ECC corrector, and an I/O circuit unit. Each of the data sensing units may include an ECC calculator that generates syndrome data for detecting an error bit from among parallel data bits read out from memory cells of each of the banks, and a data serializer that receives and converts the parallel data bits into serial data bits. The ECC corrector may correct an error bit from among the serial data bits by using the syndrome data and may output the error-corrected serial data bits to the I/O circuit unit. The I/O circuit unit may output the error-corrected serial data bits corresponding to a burst length to the data I/O pad DQ. The ECC calculator may be disposed in the data sensing unit connected to each of the banks, and the ECC corrector may be shared by the banks and may be disposed adjacent to the I/O circuit unit.

When the computer system 1600 is a device that performs wireless communication, the computer system 1600 may be used in a communication system such as a code division multiple access (CDMA) system, a global system for mobile communication (GSM) system, a North American multiple access (NADC) system, or a CDMA2000 system. The computer system 1600 may be mounted on an information processing device such as a personal digital assistant (PDA), a portable computer, a web tablet, a digital camera, a portable media player (PMP), a mobile phone, a wireless phone, or a laptop computer.

In general, a system includes a separate storage unit for storing a large amount of data such as a RAM and a cache memory having a high operating speed. One DRAM system according to some example embodiments of the inventive concepts may replace all of the memories. That is, since a large amount of data may be rapidly stored in a memory device including a DRAM according to some example embodiments of the inventive concepts, a computer system structure may be simplified.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A semiconductor memory device, comprising:
at least one bank, each of the at least one bank including a plurality of memory cells;
an error-correcting code (ECC) calculator configured to generate syndrome data for detecting an error bit from among parallel data bits read out from the plurality of memory cells of each of the at least one bank;
an ECC corrector separated from the ECC calculator, the ECC corrector configured to correct the error bit from among the parallel data bits by using the syndrome data and configured to output error-corrected parallel data bits; and
a data serializer configured to receive the error-corrected parallel data bits and configured to convert the error-corrected parallel data bits into serial data bits.

2. The semiconductor memory device of claim 1, further comprising:
data line sense amplifiers configured to sense and amplify the parallel data bits read out from the plurality of memory cells;
wherein the ECC calculator is adjacent to the data line sense amplifiers, and
wherein the ECC corrector is adjacent to the data serializer.

3. The semiconductor memory device of claim 1, wherein each of the at least one bank comprises:
a plurality of first memory cell blocks that comprise first memory cells; and
a second memory block that comprises second memory cells, and is configured to store in the second memory cells parity bits of an ECC operation for remedying a weak cell from among the first memory cells in the first memory cell blocks.

4. The semiconductor memory device of claim 3, wherein the ECC calculator is configured to receive and calculate the parallel data bits read out from the first memory cell blocks and the parity bits read out from the second memory cell block.

5. The semiconductor memory device of claim 1, further comprising:
an input/output (I/O) circuit unit configured to output to a data I/O pad the serial data bits corresponding to a burst length that are output from the data serializer.

6. The semiconductor memory device of claim 5, wherein the data serializer is configured to divide the error-corrected parallel data bits into bit groups of the burst length in response to a clock signal, and
wherein the data serializer is configured to output the bit groups as the serial data bits.

7. The semiconductor memory device of claim 5, wherein the data serializer is configured to divide the error-corrected parallel data bits into a high-order bit group and a low-order bit group of the burst length, and
wherein the data serializer is configured to output the high-order bit group and the low-order bit group as the serial data bits.

8. A semiconductor memory device, comprising:
a plurality of banks, each of the plurality of banks including a plurality of memory cells;
an error-correcting code (ECC) calculator connected to each of the plurality of banks, the ECC calculator configured to generate syndrome data for detecting an error bit from among parallel data bits read out from the plurality of memory cells;
a data serializer configured to receive the parallel data bits and configured to convert the parallel data bits into serial data bits; and
an ECC corrector configured to correct an error bit from among the serial data bits by using the syndrome data and configured to output error-corrected serial data bits.

9. The semiconductor memory device of claim 8, further comprising:
data line sense amplifiers configured to sense and amplify the parallel data bits read out from the plurality of memory cells;
wherein the ECC calculator is adjacent to the data line sense amplifiers.

10. The semiconductor memory device of claim 8, wherein the ECC corrector is shared by the plurality of banks, and
wherein the ECC corrector is configured to output the error-corrected serial data bits of each of the plurality of banks

11. The semiconductor memory device of claim 8, wherein each of the plurality of banks comprises:
a plurality of first memory cell blocks that comprise first memory cells; and
a second memory cell block that comprises second memory cells, and is configured to store in the second memory cells parity bits of an ECC operation for remedying a weak cell from among the first memory cells in the first memory cell blocks;
wherein the ECC calculator is configured to receive and calculate the parallel data bits read out from the first memory cells and the parity bits read out from the second memory cells.

12. The semiconductor memory device of claim 8, further comprising:
an input/output (I/O) circuit unit configured to output to a data I/O pad the error-corrected serial data bits corresponding to a burst length.

13. The semiconductor memory device of claim 12, wherein the ECC corrector is adjacent to the I/O circuit unit.

14. The semiconductor memory device of claim 12, wherein the data serializer is configured to divide the parallel data bits into bit groups of the burst length in response to a clock signal, and
wherein the data serializer is configured to output the bit groups as the serial data bits.

15. The semiconductor memory device of claim 12, wherein the data serializer is configured to divide the parallel data bits into a high-order bit group and a low-order bit group of the burst length, and
wherein the data serializer is configured to output the high-order bit group and the low-order bit group as the serial data bits.

16. A semiconductor memory device, comprising:
at least one bank, each of the at least one bank including a plurality of memory cells;
at least one data sensing unit that comprises an error-correcting code (ECC) calculator and a data serializer, the ECC calculator configured to generate syndrome data for detecting an error bit from among parallel data bits read out from the plurality of memory cells;
an ECC corrector configured to correct the error bit by using the syndrome data and configured to output error-corrected data bits; and
an input/output (I/O) circuit unit configured to output the error-corrected data bits.

17. The semiconductor memory device of claim 16, wherein the at least one data sensing unit includes the ECC corrector.

18. The semiconductor memory device of claim 16, wherein the data serializer is operatively connected between the ECC corrector and the I/O circuit unit.

19. The semiconductor memory device of claim 16, wherein the at least one data sensing unit does not include the ECC corrector.

20. The semiconductor memory device of claim 16, wherein
the ECC corrector is operatively connected between the ECC calculator and the I/O circuit unit, and
the ECC corrector is operatively connected between the data serializer and the I/O circuit unit.
